(19) United States
(12) Patent Application Publication
(10) Pub. No.: US 2023/0053074 A1
(43) Pub. Date: Feb. 16, 2023

(54) SEMICONDUCTOR DEVICE AND MANUFACTURING METHOD THEREOF

(71) Applicant: GLC SEMI CONDUCTOR GROUP (SH) CO., LTD., Shanghai (CN)

(72) Inventors: Che-Jui Chang, Changhua County (TW); Chi-Ching Pu, Hsinchu County (TW); Shun-Min Yeh, Hsinchu City (TW)

(73) Assignee: GLC SEMI CONDUCTOR GROUP (SH) CO., LTD., Shanghai (CN)

(21) Appl. No.: 17/400,123

(22) Filed: Aug. 12, 2021

(51) Int. Cl. H01L 29/778; H01L 29/06; H01L 29/66

(52) U.S. Cl. CPC H01L 29/7786; H01L 29/0649; H01L 29/66462

(57) ABSTRACT

A semiconductor device includes at least one active region, a first dielectric layer, a gate structure, and an air void. The active region includes a III-V compound semiconductor layer. The first dielectric layer is disposed on the active region. The gate structure is disposed on the active region, and at least a part of the gate structure is disposed in the first dielectric layer. The air void is disposed in the first dielectric layer, and at least a part of the air void is disposed at two opposite sides of the gate structure in a horizontal direction.

### BACKGROUND OF THE INVENTION

### 1. Field of the Invention

The present invention relates to a semiconductor device and a manufacturing method thereof, and more particularly, to a semiconductor device including an air void and a manufacturing method thereof.

### 2. Description of the Prior Art

Because of the semiconductor characteristics, III-V semiconductor compounds may be applied in many kinds of integrated circuit devices, such as high power field effect transistors, high frequency transistors, or high electron mobility transistors (HEMTs). In recent years, gallium nitride (GaN) based materials have been applied in the high power and high frequency products because of the properties of wider band-gap and high saturation velocity. Two-dimensional electron gas (2DEG) may be generated by the piezoelectricity property of the GaN-based materials, and the switching velocity may be enhanced because of the higher electron velocity and the higher electron density of the 2DEG. However, with demands for higher performance of the related semiconductor devices, the structural design and/or the process design have to be modified continuously for improving the operation performance of the transistor and satisfying the product specifications.

### SUMMARY OF THE INVENTION

It is one of the objectives of the present invention to provide a semiconductor device and a manufacturing method thereof. An air void is disposed in a dielectric layer on an active region, and a gate structure is disposed on the active region and at least partially disposed in the dielectric layer. At least a part of the air void is disposed at two opposite sides of a gate structure in a horizontal direction for improving operation performance of the semiconductor device.

A semiconductor device is provided in an embodiment of the present invention. The semiconductor device includes at least one active region, a first dielectric layer, a gate structure, and an air void. The active region includes a III-V compound semiconductor layer. The first dielectric layer is disposed on the active region. The gate structure is disposed on the active region, and at least a part of the gate structure is disposed in the first dielectric layer. The air void is disposed in the first dielectric layer, and at least a part of the air void is disposed at two opposite sides of the gate structure in a horizontal direction.

A manufacturing method of a semiconductor device is provided in an embodiment of the present invention. The manufacturing method includes the following steps. At least one active region is provided, and the at least one active region includes a III-V compound semiconductor layer. A dielectric layer is formed on the at least one active region. An air void is formed in the dielectric layer. A gate structure is formed on the at least one active region. At least a part of the gate structure is formed in the dielectric layer, and at least a part of the air void is disposed at two opposite sides of the gate structure in a horizontal direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a semiconductor device according to a first embodiment of the present invention.

FIGS. 2-13 are schematic drawings illustrating a manufacturing method of a semiconductor device according to a first embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, FIG. 11 is a schematic drawing in a step subsequent to FIG. 10, FIG. 12 is a schematic drawing in a step subsequent to FIG. 11, and FIG. 13 is a schematic drawing in a step subsequent to FIG. 12.

FIG. 14 is a schematic drawing illustrating a semiconductor device according to a second embodiment of the present invention.

FIG. 15 and FIG. 16 are schematic drawings illustrating a manufacturing method of a semiconductor device according to a second embodiment of the present invention, wherein FIG. 16 is a schematic drawing in a step subsequent to FIG. 15.

FIG. 17 is a schematic drawing illustrating a semiconductor device according to a third embodiment of the present invention.

FIG. 18 is a schematic drawing illustrating a manufacturing method of a semiconductor device according to a third embodiment of the present invention.

FIG. 19 is a schematic drawing illustrating a semiconductor device according to a fourth embodiment of the present invention.

FIG. 20 is a schematic drawing illustrating a manufacturing method of a semiconductor device according to a fourth embodiment of the present invention.

FIG. 21 is a schematic drawing illustrating a top view of a semiconductor device according to an embodiment of the present invention.

FIG. 22 is a schematic drawing illustrating a top view of a semiconductor device according to another embodiment of the present invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

It is noted that references in the specification to “one embodiment,” “an embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

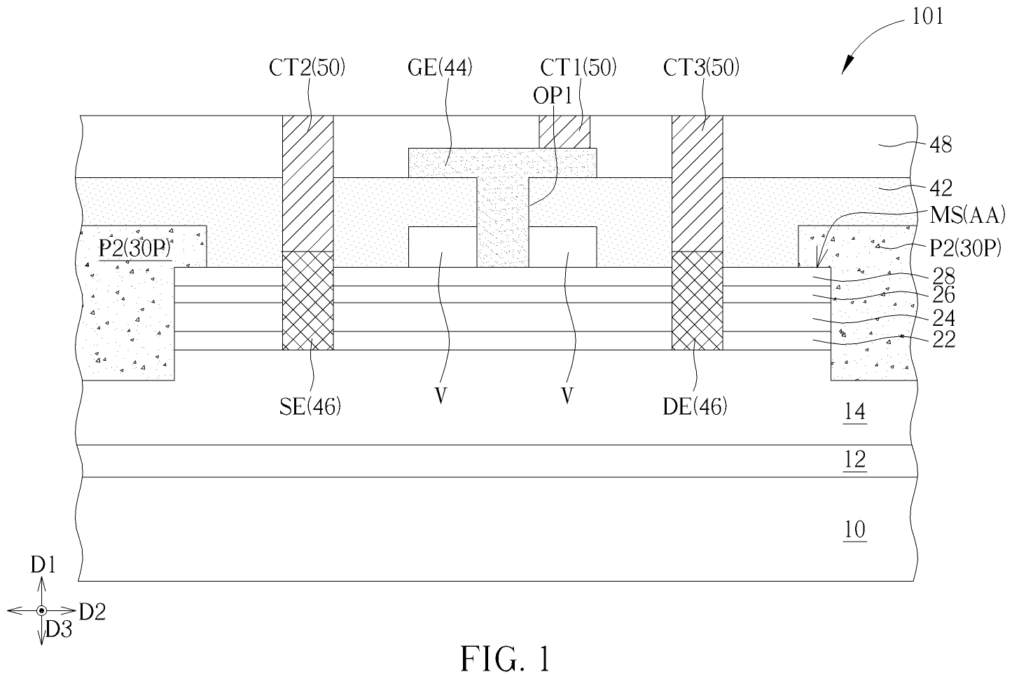

Please refer to FIG. 1. FIG. 1 is a schematic drawing illustrating a semiconductor device 101 according to a first embodiment of the present invention. As shown in FIG. 1, the semiconductor device 101 includes at least one active region AA, a first dielectric layer (such as a dielectric layer 42 shown in FIG. 1), a gate structure GE, and an air void V. The active region AA includes a III-V compound semiconductor layer 14. The dielectric layer 42 is disposed on the active region AA. The gate structure GE is disposed on the active region AA, and at least a part of the gate structure GE is disposed in the dielectric layer 42. The air void V is disposed in the dielectric layer 42, and at least a part of the air void V is disposed at two opposite sides of the gate structure GE in a horizontal direction (such as a second direction D2 shown in FIG. 1, but not limited thereto). The air void V may be disposed adjacent to the gate structure GE for reducing trapped electrons and/or detrapped electrons from the gate structure GE and/or around the gate structure GE, some phenomenon, such as gate-lag, in the semiconductor device 101 may be improved, and operation performance and/or reliability of the semiconductor device 101 may be enhanced accordingly.

In some embodiments, the active region AA may include a mesa structure MS disposed on a substrate 10, and a buffer layer 12 may be disposed between the substrate 10 and the active region AA, but not limited thereto. The substrate 10 may have a top surface and a bottom surface opposite to the top surface in a thickness direction of the substrate 10 (such as a first direction D1 shown in FIG. 1), and the buffer layer 12, the active region AA, the gate structure GE, the dielectric layer 42, and the air void V may be disposed at a side of the top surface of the substrate 10. A horizontal direction substantially orthogonal to the first direction D1 (such as a second direction D2 and a third direction D3 shown in FIG. 1) may be substantially parallel with the top surface and/or the bottom surface of the substrate 10, but not limited thereto. Additionally, in this description, a distance between the top surface of the substrate 10 and a relatively higher location and/or a relatively higher part in a vertical direction (such as the first direction D1) may be greater than a distance between the top surface of the substrate 10 and a relatively lower location and/or a relatively lower part in the first direction D1. The bottom or a lower portion of each component may be closer to the top surface of the substrate 10 in the first direction D1 than the top or upper portion of this component. Another component disposed above a specific component may be regarded as being relatively far from the top surface of the substrate 10 in the first direction D1, and another component disposed under a specific component may be regarded as being relatively closer to the top surface of the substrate 10 in the first direction D1, but not limited thereto.

In some embodiments, the air void V may surround a bottom portion of the gate structure GE in the dielectric layer 42, and the air void V may be directly connected with the gate structure GE in the dielectric layer 42. For example, the air void V may surround the bottom portion of the gate structure GE in the horizontal directions (such as the second direction D2 and/or the third direction D3), and a top portion of the gate structure GE disposed in the dielectric layer 42 may be surrounded and directly connected with the dielectric layer 42 in the horizontal directions. In some embodiments, the gate structure GE may be partly disposed in the dielectric layer 42 and partly disposed on the dielectric layer 42 in the first direction D1, and a part of the dielectric layer 42 may be located between the gate structure GE and the air void V in the first direction D1 accordingly, but not limited thereto. The air void V in the dielectric layer 42 may be used to lower equivalent dielectric constant of the material around the gate structure GE, the density of trapped electrons and/or detrapped electrons from the gate structure GE and/or around the gate structure GE may be reduced accordingly, and some related issues of the semiconductor device 101 (such as gate-lag, current collapse, and so forth) may be improved.

In some embodiments, the substrate 10 may include a silicon substrate, a silicon carbide (SiC) substrate, a gallium nitride (GaN) substrate, a sapphire substrate, or a substrate formed with other appropriate materials, and the buffer layer 12 may include a buffer material beneficial for forming the III-V compound semiconductor layer 14 on the substrate 10 by an epitaxial growth approach, but not limited thereto. For example, the buffer layer 12 may include gallium nitride, aluminum gallium nitride (AlGaN), or other suitable buffer materials. In some embodiments, the III-V compound semiconductor layer 14 may be regarded as a semiconductor channel layer in the semiconductor device 101, and the III-V compound semiconductor layer 14 may be made of gallium nitride, indium gallium nitride (InGaN), and/or other suitable III-V compound semiconductor materials. In some embodiments, the III-V compound semiconductor layer 14 may be a single layer or multiple layers of the III-V compound materials described above, and the active region AA may further include other material layers (such as a barrier layer 22, a barrier layer 24, a barrier layer 26, and a cap layer 28 shown in FIG. 1) disposed on the III-V compound semiconductor layer 14 and stacked in the first direction D1, but not limited thereto. In some embodiments, the barrier layer 22, the barrier layer 24, and the barrier layer 26 may include aluminum gallium nitride, aluminum nitride (AlN), aluminum indium nitride (AlInN), or other suitable III-V compound barrier materials, respectively, and the cap layer 28 may gallium nitride, aluminum gallium nitride, aluminum nitride, or other suitable materials. For example, the barrier layer 22 and the barrier layer 26 may be aluminum nitride layers, and the barrier layer 24 may be an aluminum gallium nitride layer sandwiched between the two aluminum nitride layers, but not limited thereto. In addition, the thicknesses of the barrier layers described above may be adjusted for modifying the electrical performance of the semiconductor device 101. For example, the barrier layer 22 may be thinner than the barrier layer 26, but not limited thereto.

In some embodiments, the semiconductor device 101 may further include a first source/drain electrode SE and a second source/drain electrode DE. The first source/drain electrode SE and the second source/drain electrode DE may be disposed at two opposite sides of at least a part of the gate structure GE in the second direction D2, respectively. In some embodiments, the first source/drain electrode SE may be a source electrode of a transistor including the gate structure GE and the second source/drain electrode DE may be a drain electrode of the transistor including the gate structure GE, but not limited thereto. In other words, the first source/drain electrode SE and the second source/drain electrode DE may be a drain electrode and a source electrode of the transistor including the gate structure GE, respectively. In some embodiments, the first source/drain electrode SE and the second source/drain electrode DE may penetrate through a part of the active region AA in the first direction D1. For example, the first source/drain electrode SE and the second source/drain electrode DE may penetrate through the cap layer 28, the barrier layer 26, the barrier layer 24, and the barrier layer 22 in the first direction D1, but not limited thereto. In addition, a part of the air void V may be disposed between the gate structure GE and the first source/drain electrode SE in the second direction D2, and another part of the air void V may be disposed between the gate structure GE and the second source/drain electrode DE in the second direction D2.

In addition, the semiconductor device 101 may further include a dielectric layer 48, a contact structure CT1, a contact structure CT2, and a contact structure CT3. The dielectric layer 48 may be disposed on the dielectric layer 42 and cover the gate structure GE disposed on the dielectric layer 42. The contact structure CT1 may penetrate through the dielectric layer 48 on the gate structure GE in the first direction D1 for contacting and being electrically connected with the gate structure GE, the contact structure CT2 may penetrate through the dielectric layer 48 and a part of the dielectric layer 42 in the first direction D1 for contacting and being electrically connected with the first source/drain electrode SE, and the contact structure CT3 may penetrate through the dielectric layer 48 and a part of the dielectric layer 42 in the first direction D1 for contacting and being electrically connected with the second source/drain electrode DE. In some embodiments, the gate structure GE, the first source/drain electrode SE, and the second source/drain electrode DE may respectively include conductive metal materials or other suitable conductive materials. The conductive metal materials mentioned above may include gold (Au), tungsten (W), cobalt (Co), nickel (Ni), titanium (Ti), molybdenum (Mo), copper (Cu), aluminum (Al), tantalum (Ta), palladium (Pd), platinum (Pt), a compound of the above-mentioned materials, a stack layer of the above-mentioned materials, or an alloy of the above-mentioned materials, but not limited thereto. The dielectric layer 42 and the dielectric layer 48 may include silicon oxide, silicon nitride, silicon oxynitride, or other suitable dielectric materials. The contact structure CT1, the contact structure CT2, and the contact structure CT3 may respectively include a conductive barrier layer (not illustrated) and a metal layer (not illustrate) disposed on the conductive barrier layer. The conductive barrier layer may include titanium (Ti), titanium nitride (TiN), tantalum (Ta), tantalum nitride (TaN) or other suitable barrier materials, and the metal layer may include tungsten, copper, aluminum, titanium aluminide (TiAl), cobalt tungsten phosphide (CoWP), or other suitable metallic materials.

In some embodiments, the semiconductor device 101 may further include a second dielectric layer (such as a patterned material layer 30P shown in FIG. 1) disposed on a sidewall of the active region AA, and a material composition of the patterned material layer 30P may be different from a material composition of the dielectric layer 42 for providing required etching selectivity in the process of forming the air void V. For example, the patterned material layer 30P may be an oxide dielectric layer while the dielectric layer 42 is a nitride dielectric layer, and the patterned material layer 30P may be used to protect the active region by covering the sidewall of the active region AA during the step of forming the air void V.

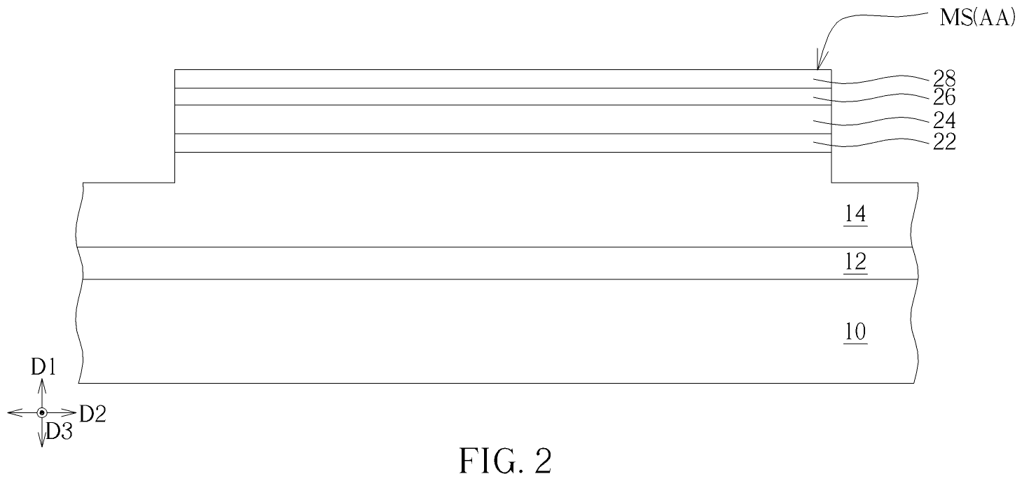

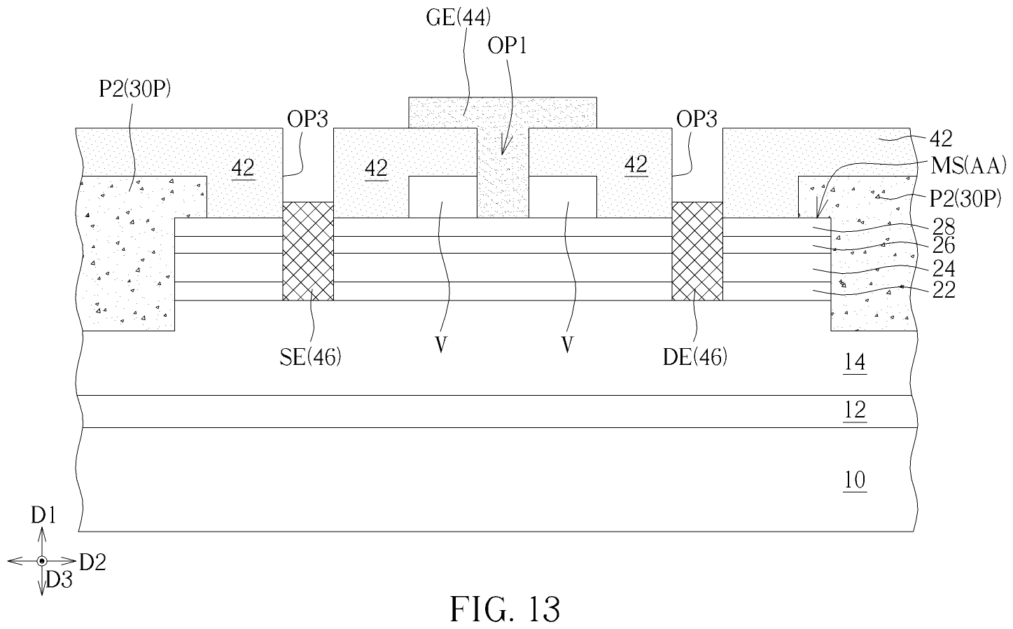

Please refer to FIGS. 2-13 and FIG. 1. FIGS. 2-13 are schematic drawings illustrating a manufacturing method of a semiconductor device according to the first embodiment of the present invention. In some embodiments, FIG. 1 may be regarded as a schematic drawing in a step subsequent to FIG. 13, but not limited thereto. As shown in FIG. 1, a manufacturing method of the semiconductor device 101 may include the following steps. At least one active region AA is provided, and the active region AA includes the III-V compound semiconductor layer 14. The dielectric layer 42 is formed on the active region AA. The air void V is formed in the dielectric layer 42. The gate structure GE is formed on the active region. At least a part of the gate structure GE is formed in the dielectric layer 42, and at least a part of the air void V is disposed at two opposite sides of the gate structure GE in a horizontal direction (such as the second direction D2 shown in FIG. 1).

Specifically, the manufacturing method of the semiconductor device 101 in this embodiment may include but is not limited to the following steps. Firstly, as shown in FIG. 2, at least one active region AA may be formed on the substrate 10. In some embodiments, the buffer layer 12, the III-V compound semiconductor layer 14, the barrier layer 22, the barrier layer 24, the barrier layer 26, and the cap layer 28 may be sequentially formed and stacked on the substrate 10. Subsequently, a patterning process (such as a photolithography process or other suitable patterning approaches) may be carried out for patterning the material layers stacked on the substrate 10, and the material layers may be patterned to be one or more active regions AA accordingly. Therefore, the active region AA in this embodiment may be regarded as a mesa structure MS formed on the substrate 10, but not limited thereto. In some embodiments, the active region AA may also be formed by other manufacturing approaches and/or other material compositions different from those described above according to other design considerations.

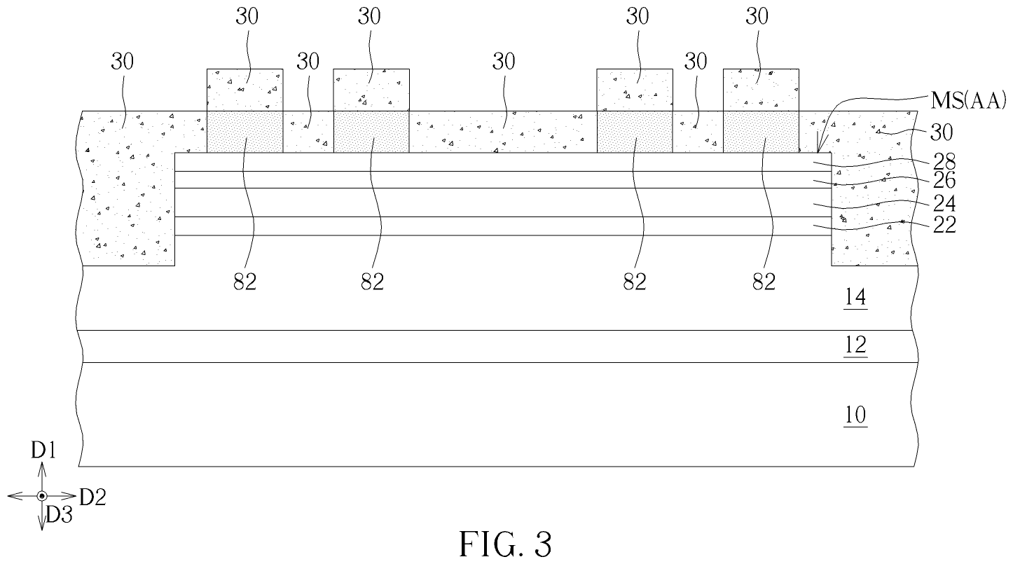

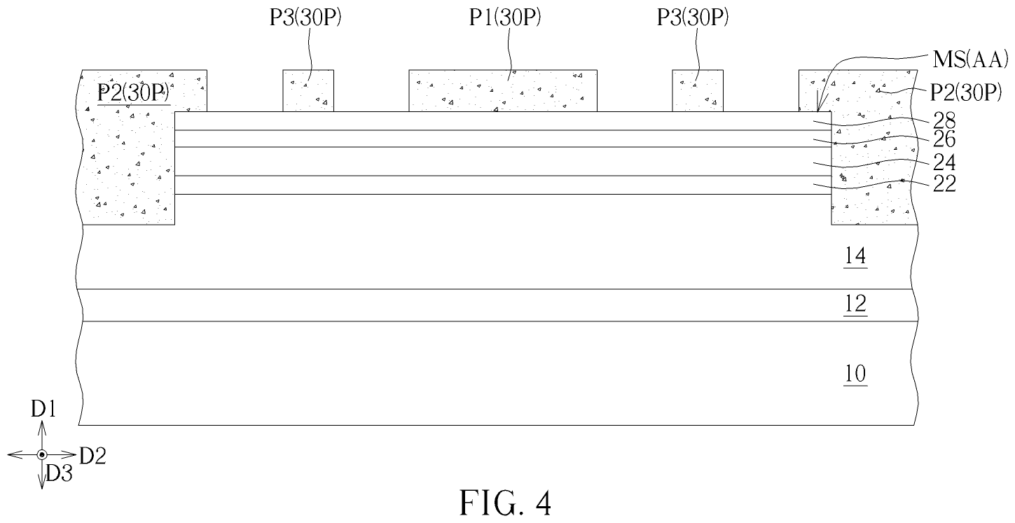

As shown in FIGS. 3-8, the method of forming the air void V described above may include but is not limited to the following steps. As shown in FIG. 3, a patterned photoresist layer 82 may be formed on the active region AA, and a material layer 30 may be formed on the active region AA and the patterned photoresist layer 82. A portion of the material layer 30 may be formed on the patterned photoresist layer 82 in the first direction D1, a portion of the material layer 30 may be formed between different sections of the patterned photoresist layer 82 in the horizontal direction, and a portion of the material layer 30 may be formed on the sidewall of the active region AA. As shown in FIG. 3 and FIG. 4, the patterned photoresist layer 82 and the portion of the material layer 30 formed on the patterned photoresist layer 82 in the first direction D1 may be removed by a photoresist stripper process for forming a patterned material layer 30P. In other words, the patterned material layer 30P may be formed by a lift-off process, and the material layer 30 remaining on the substrate 10 after the step of removing the patterned photoresist layer 82 may become the patterned material layer 30P.

The material layer 30 may include a metal material, a dielectric material, or other suitable materials for providing required etching selectivity in the subsequent process configured to form the air void. In some embodiments, the patterned material layer 30P may include a first portion P1, a second portion P2, and a third portion P3 separated from one another. The first portion P1 may be disposed on the active region AA in the first direction D1, the second portion P2 may be partly disposed on the active region AA in the first direction D1 and partly disposed on the sidewall of the active region AA in the horizontal direction, and the third portion P3 may be disposed between the first portion P1 and the second portion P2 in the horizontal direction. It is worth noting that the method of forming the patterned material layer 30P is not limited to the steps described above and may be formed by other suitable approaches according to some design considerations. In addition, the second portion P2 of the patterned material layer 30P may be used to protect the active region AA during the step of removing the patterned photoresist layer 82 especially when the barrier layers and/or the III-V compound semiconductor layer 14 tends to be influenced by the chemicals used in the step of removing the patterned photoresist layer 82.

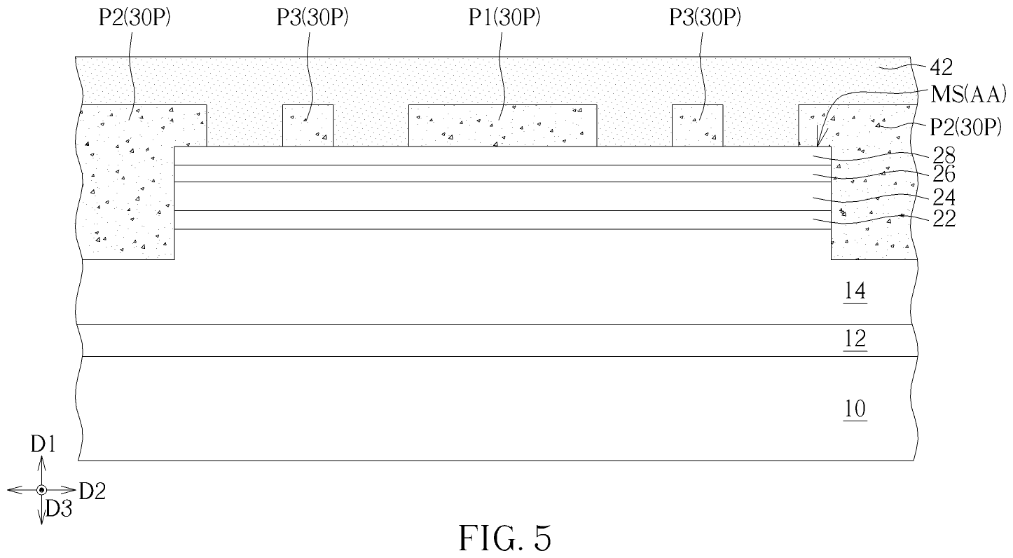

As shown in FIG. 5, the dielectric layer 42 is formed after the step of forming the patterned material layer 30P, and the dielectric layer 42 may cover the active region AA and the first portion P1, the second portion P2, and the third portion P3 of the patterned material layer 30P in the first direction D1. Additionally, a part of the dielectric layer 42 may be formed between the first portion P1 and the third portion P3 of the patterned material layer 30P, and another part of the dielectric layer 42 may be formed between the second portion P2 and the third portion P3 of the patterned material layer 30P. The air void described above may be formed in the dielectric layer 42 by removing the first portion P1 of the patterned material layer 30P after the dielectric layer 42 is formed.

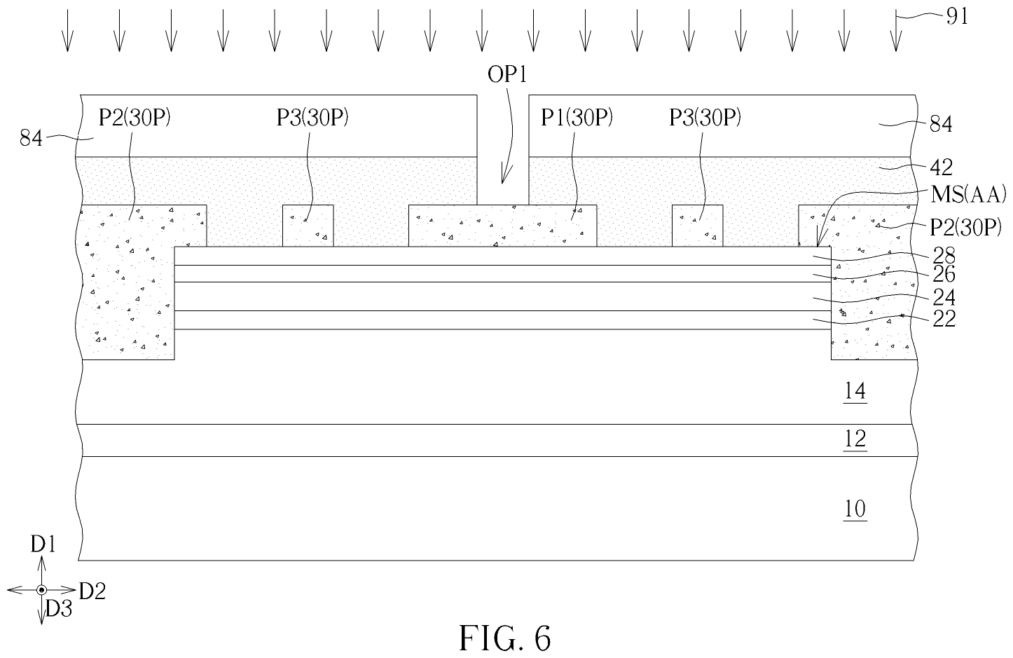

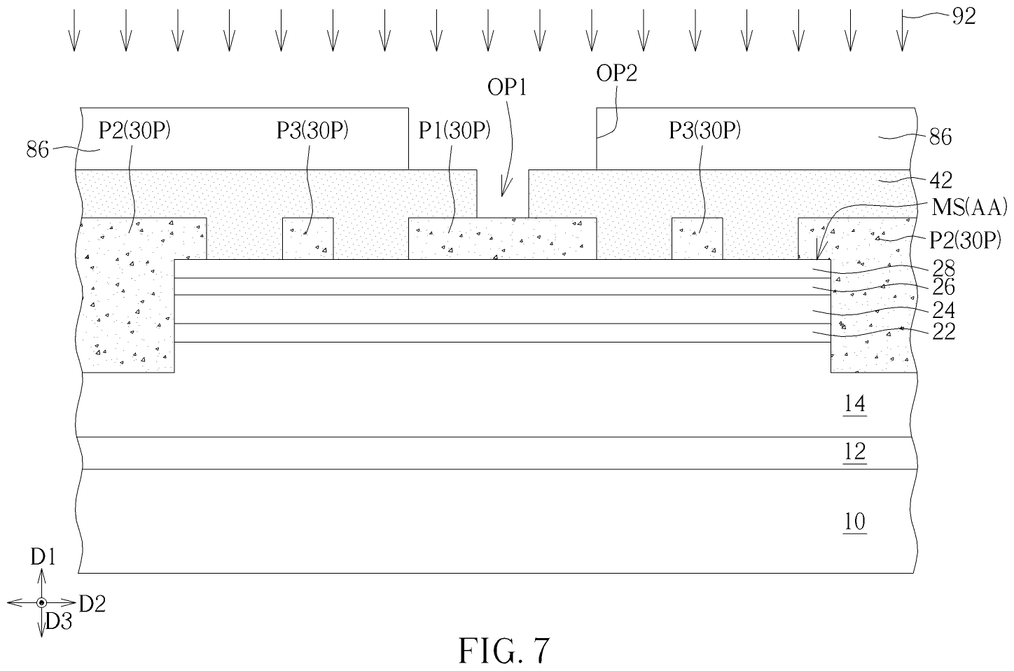

As shown in FIG. 5 and FIG. 6, a patterned photoresist layer 84 may be formed on the dielectric layer 42, and an etching process 91 may be carried out by using the patterned photoresist layer 84 as an etching mask for forming a first opening OP1 in the dielectric layer 42. The first opening OP1 may penetrate through the dielectric layer 42 on the first portion P1 of the patterned material layer 30P in the first direction D1 for exposing the first portion P1 of the patterned material layer 30P before the step of removing the first portion P1 of the patterned material layer 30P. In some embodiments, as shown in FIG. 6 and FIG. 7, the patterned photoresist layer 84 may be removed after the step of forming the first opening OP1, and a patterned photoresist layer 86 including a second opening OP2 located corresponding to the first opening OP1 and the first portion P1 of the patterned material layer 30P in the first direction D1 may be formed on the dielectric layer 42. After the step of forming the patterned photoresist layer 86, an etching process 92 may be carried out for removing the first portion P1 of the patterned material layer 30P. In other words, the first opening OP1 and the patterned photoresist layer 86 including the second opening OP2 may be formed before the step of removing the first portion P1 of the patterned material layer 30P. In some embodiments, a projection area of the second opening OP2 in the first direction D1 may be greater than a projection area of the first opening OP1 in the first direction D1 for removing the first portion P1 of the patterned material layer 30P in the etching process 92 more easily.

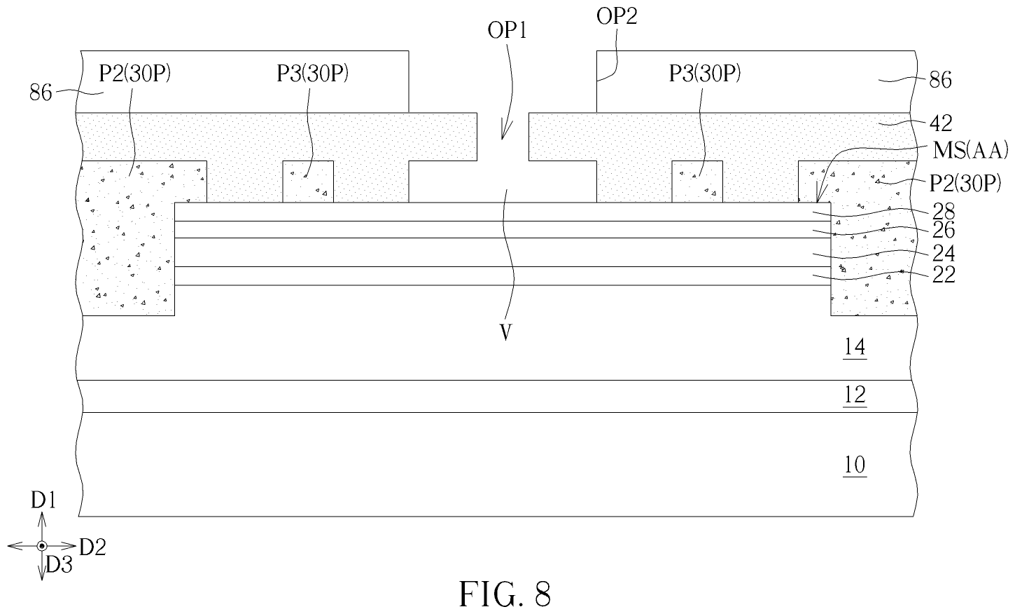

As shown in FIG. 7 and FIG. 8, the first portion P1 of the patterned material layer 30P may be removed by the etching process 92 for forming the air void V in the dielectric layer 42. The material composition of the patterned material layer 30P may be different from the material composition of the dielectric layer 42 for providing the required etching selectivity in the etching process 92, and the shape and the area of the air void V may be controlled more precisely while the first portion P1 of the patterned material layer 30P may be completely removed by the etching process 92 and the etching loss of the dielectric layer 42 in the etching process 92 may be reduced as much as possible. In addition, the second portion P2 and the third portion P3 of the patterned material layer 30P may be covered by the dielectric layer 42 during the etching process 92 and after the air void V is formed.

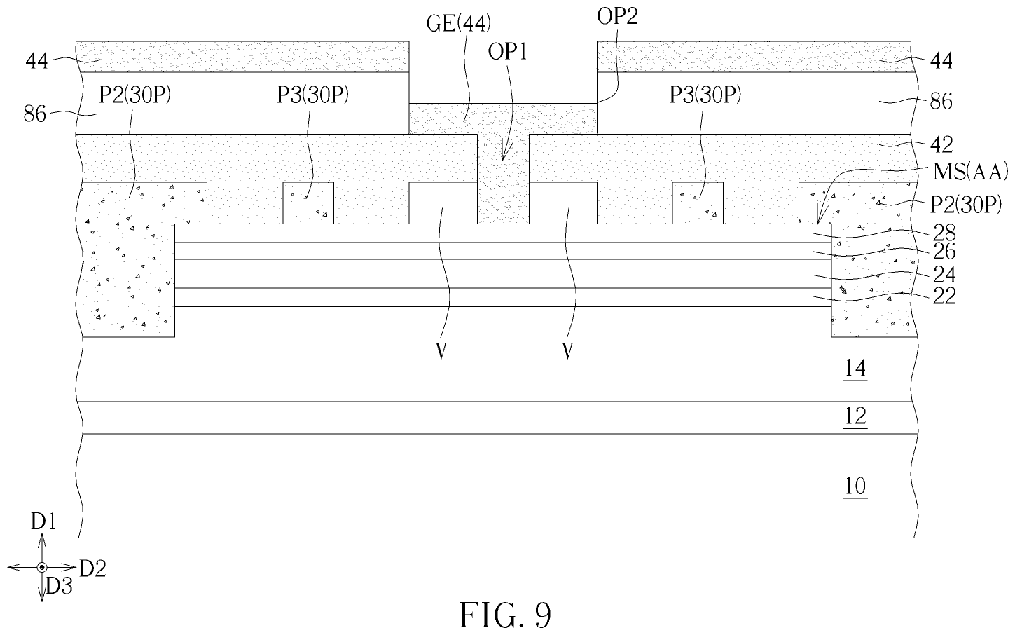

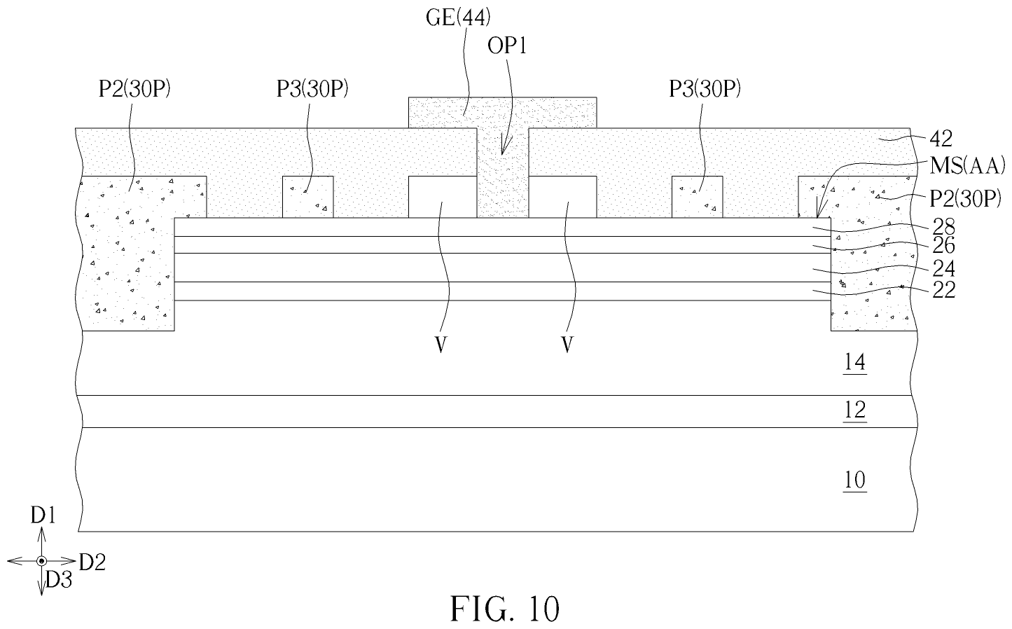

As shown in FIGS. 8-10, the gate structure GE may be formed after the step of forming the air void V. In some embodiments, the step of forming the gate structure GE may include but is not limited to the following step. As shown in FIG. 9, a conductive material 44 may be formed after the air void V is formed. The conductive material 44 may be partly formed on the patterned photoresist layer 86, partly formed on the dielectric layer 42, and partly formed in the dielectric layer 42. In some embodiments, the conductive material 44 may be formed by a sputtering process or other suitable film forming processes with relatively poor gap-filling performance for keeping the air void V in the dielectric layer 42 after the step of forming the gate structure GE. As shown in FIG. 9 and FIG. 10, the patterned photoresist layer 86 and the conductive material 44 on the patterned photoresist layer 86 may be removed concurrently by a photoresist stripper process for forming the gate structure GE. In other words, the gate structure GE may be formed by a lift-off process, the conductive material 44 remaining on the substrate 10 after the step of removing the patterned photoresist layer 86 may become the gate structure GE, and the patterned photoresist layer 86 may be used in the step of forming the air void V and the step of forming the gate structure GE for process simplification. In some embodiments, the gate structure GE may also be formed by other manufacturing approaches different from the manufacturing steps described above according to other design considerations.

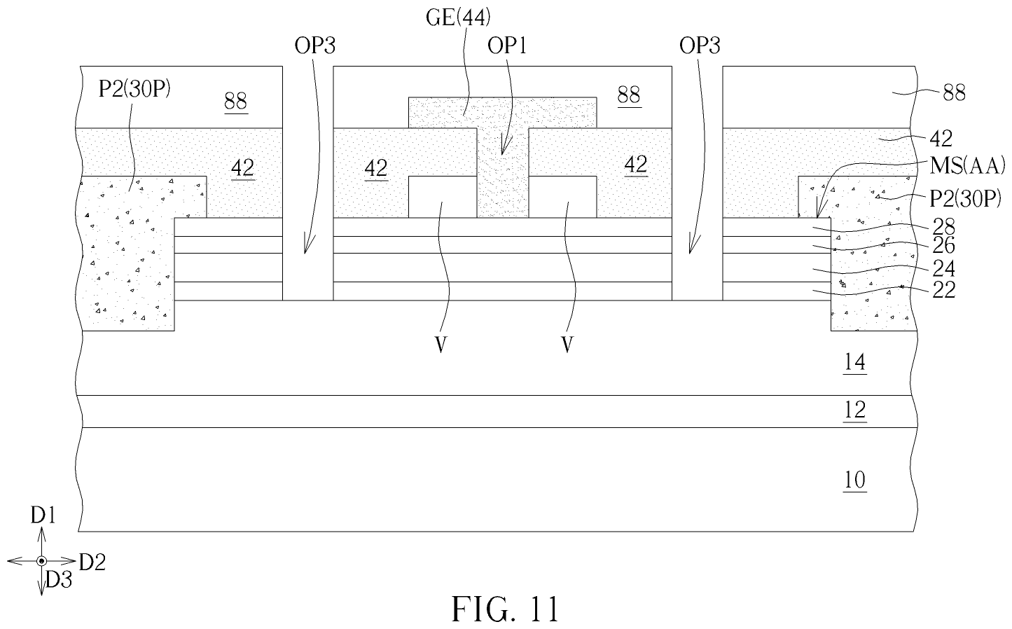

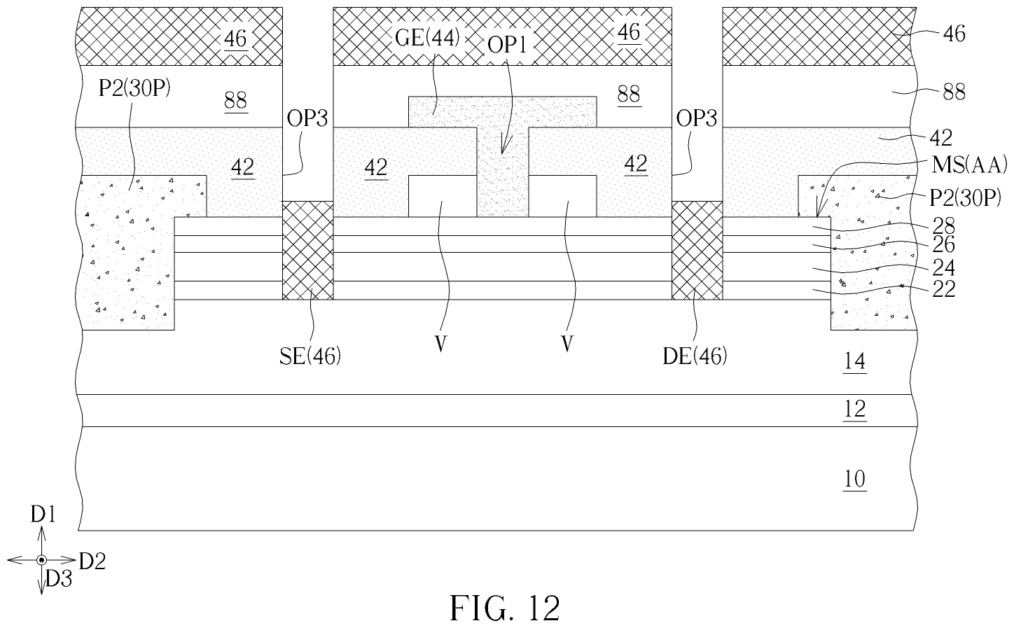

As shown in FIGS. 11-13, the first source/drain electrode SE and the second source/drain electrode DE may be formed after the step of forming the gate structure GE. The method of forming the first source/drain electrode SE and the second source/drain electrode DE may include but is not limited to the following steps. As shown in FIG. 11, a patterned photoresist layer 88 may be formed on the dielectric layer 42 and the gate structure GE, and an etching process using the patterned photoresist layer 88 as an etching mask may be carried out for forming third openings OP3 penetrating through the dielectric layer 42, the third portion P3 of the patterned material layer 30P, the cap layer 28, the barrier layer 26, the barrier layer 24, and the barrier layer 22 in the first direction D1. In some embodiments, the third portion P3 of the patterned material layer 30P may be completely removed by the step of forming the third openings OP3, and the third portion P3 of the patterned material layer 30P may be used as an etching stop layer between the step of etching the dielectric layer 42 and the step of etching the cap layer 28 for controlling the shape and/or the depth of the third opening OP3 more precisely, but not limited thereto. Subsequently, as shown in FIG. 12, a conductive material 46 may be formed after the third openings OP3 are formed. The conductive material 46 may be partly formed on the patterned photoresist layer 88 and partly formed in the third openings OP3. As shown in FIG. 12 and FIG. 13, the patterned photoresist layer 88 and the conductive material 46 on the patterned photoresist layer 88 may be removed concurrently by a photoresist stripper process for forming the first source/drain electrode SE and the second source/drain electrode DE. In other words, the first source/drain electrode SE and the second source/drain electrode DE may be formed by a lift-off process, and the conductive material 46 remaining on the substrate 10 after the step of removing the patterned photoresist layer 88 may become the first source/drain electrode SE and the second source/drain electrode DE.

As shown in FIG. 13 and FIG. 1, after the step of forming the first source/drain electrode SE and the second source/drain electrode DE, the dielectric layer 48, the contact structure CT1, the contact structure CT2, and the contact structure CT3 may be formed for forming the semiconductor device 101 shown in FIG. 1. In some embodiments, the contact structure CT1, the contact structure CT2, and the contact structure CT3 may be formed concurrently by the same process, such as a process of forming a conductive material 50 in an opening penetrating through the dielectric layer 48 above the gate structure GE, an opening penetrating through the dielectric layer 48 and the dielectric layer 42 above the first source/drain electrode SE, and an opening penetrating through the dielectric layer 48 and the dielectric layer 42 above the second source/drain electrode DE, respectively, but not limited thereto.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

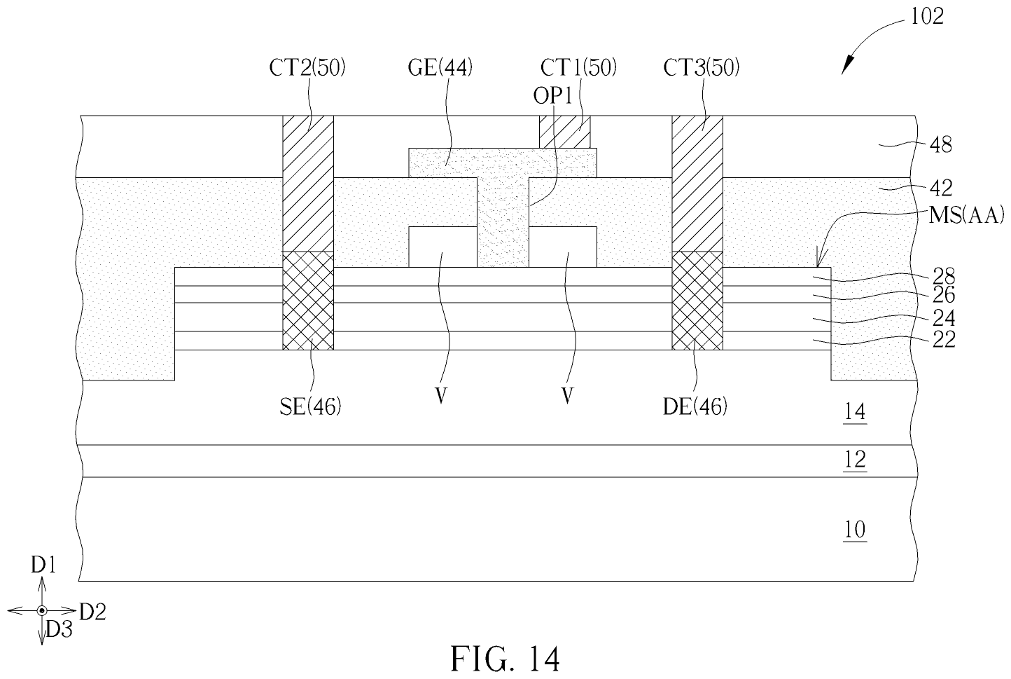

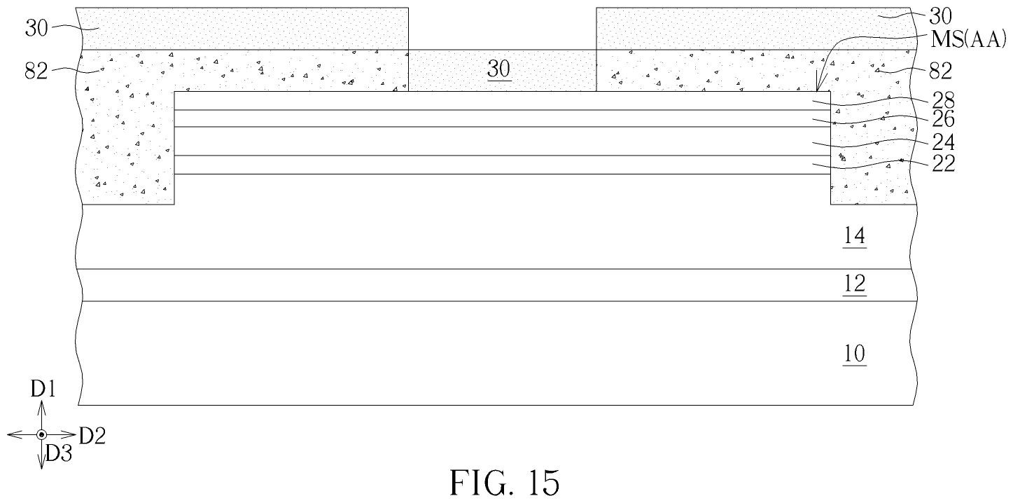

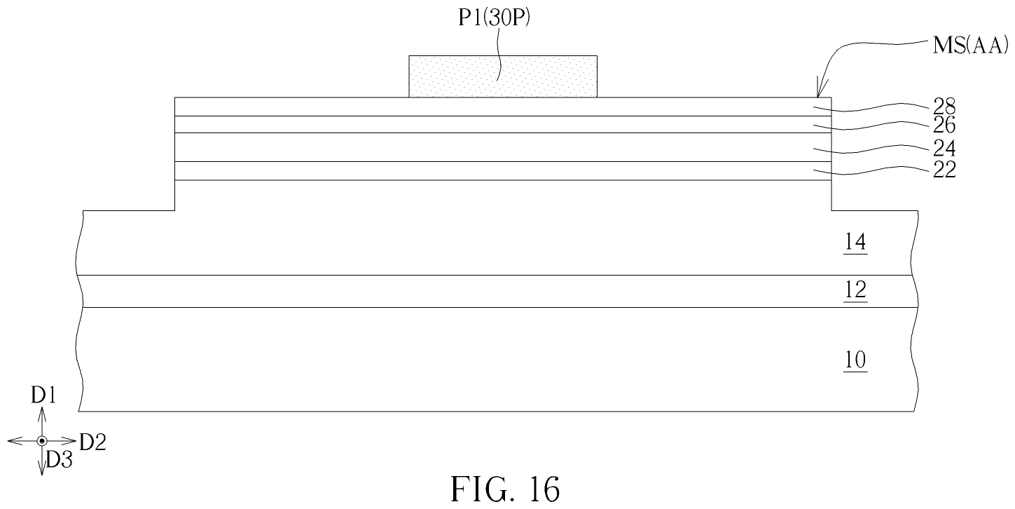

Please refer to FIG. 14. FIG. 14 is a schematic drawing illustrating a semiconductor device 102 according to a second embodiment of the present invention. As shown in FIG. 14, in the semiconductor device 102, the dielectric layer 42 may directly cover the sidewall of the active region AA without the third portion of the patterned material layer in the first embodiment described above. Please refer to FIGS. 14-16. FIG. 15 and FIG. 16 are schematic drawings illustrating a manufacturing method of the semiconductor device 102 according to the second embodiment of the present invention. In some embodiments, FIG. 14 may be regarded as a schematic drawing in a step subsequent to FIG. 16, but not limited thereto. As shown in FIG. 15, the patterned photoresist layer 82 formed before the step of forming the material layer 30 may cover the sidewall of the active region AA. As shown in FIG. 15 and FIG. 16, the patterned photoresist layer 82 and the portion of the material layer 30 formed on the patterned photoresist layer 82 in the first direction D1 may be removed by a photoresist stripper process for forming the patterned material layer 30P including the first portion P1 without the second portion and the third portion of the patterned material layer 30P in the first embodiment described above. In this embodiment, the material layer 30 may be a conductive metal layer preferably for further enhancing the etching selectivity in the step of forming the air void V, but not limited thereto. It is worth noting that the patterned material layer 30P in this embodiment may also be applied to other embodiments of the present invention according to some design considerations.

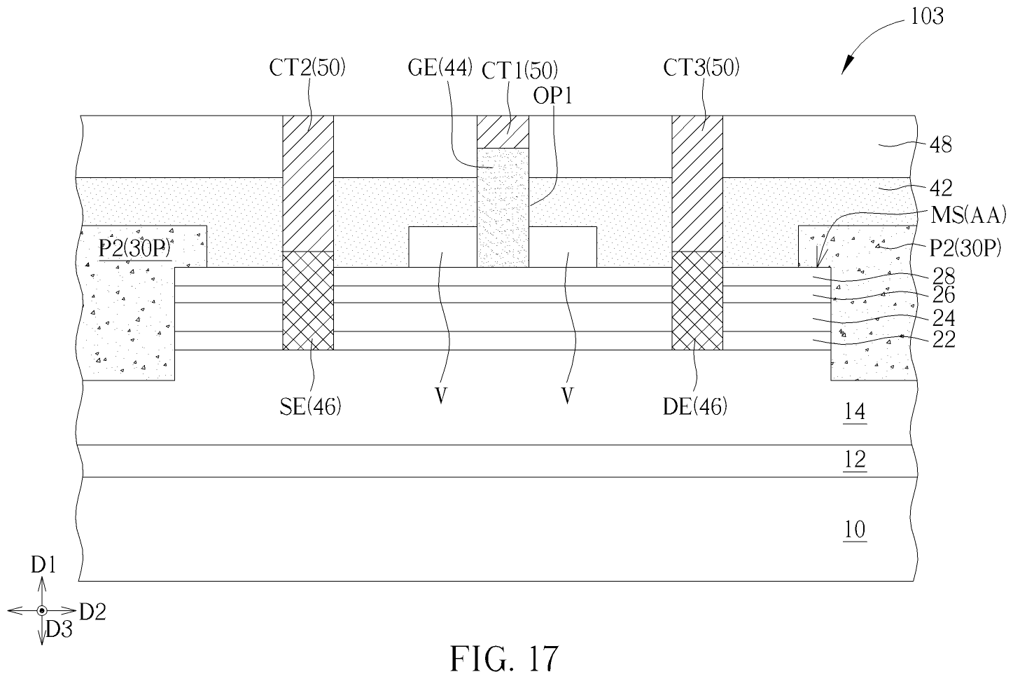

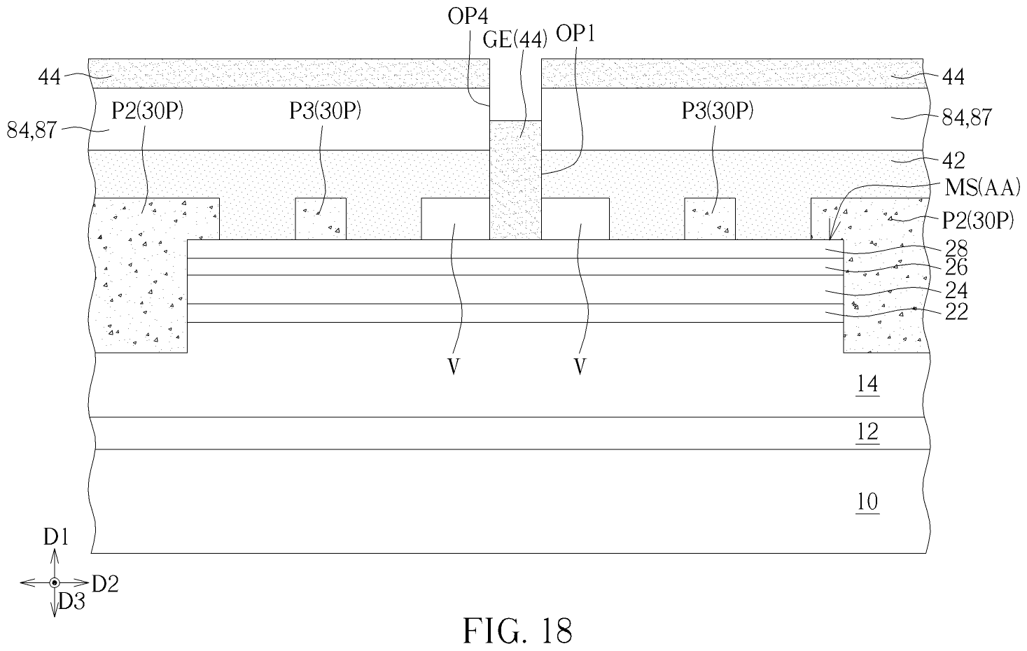

Please refer to FIG. 17. FIG. 17 is a schematic drawing illustrating a semiconductor device 103 according to a third embodiment of the present invention. As shown in FIG. 17, the gate structure GE may have an I-shaped structure in a cross-sectional diagram of the semiconductor device 103, and the gate structure GE may not be disposed on the dielectric layer 42 in the first direction D1 accordingly. Please refer to FIG. 6, FIG. 17, and FIG. 18. FIG. 18 is a schematic drawing illustrating a manufacturing method of the semiconductor device 103 according to the third embodiment of the present invention. In some embodiments, FIG. 17 may be regarded as a schematic drawing in a step subsequent to FIG. 18, and FIG. 18 may be regarded as a schematic drawing in a step subsequent to FIG. 6, but not limited thereto. As shown in FIG. 6 and FIG. 18, the method of forming the gate structure GE may include the following steps. The first opening OP1 may be formed by the etching process 91 using the patterned photoresist layer 84 formed on the dielectric layer 42 as an etching mask. The first portion P1 of the patterned material layer 30P may then be removed for forming the air void V, and the patterned photoresist layer 84 may remain on the dielectric layer 42 after the air void V is formed. Subsequently, the conductive material 44 may be formed after the air void V is formed. The conductive material 44 may be partly formed on the patterned photoresist layer 84 and partly formed in the dielectric layer 42. The patterned photoresist layer 84 and the conductive material 44 on the patterned photoresist layer 84 may then be removed for forming the gate structure GE. In other words, the patterned photoresist layer 84 may be used in the step of forming the first opening OP1, the step of forming the air void V, and the step of forming the gate structure GE for process simplification, but not limited thereto.

Please refer to FIG. 8, FIG. 17, and FIG. 18. In some embodiments, FIG. 17 may be regarded as a schematic drawing in a step subsequent to FIG. 18, and FIG. 18 may be regarded as a schematic drawing in a step subsequent to FIG. 8, but not limited thereto. As shown in FIG. 8 and FIG. 18, the patterned photoresist layer 86 may be removed after the air void V is formed, and a patterned photoresist layer 87 may be formed on the dielectric layer 42 after the patterned photoresist layer 86 is removed. The patterned photoresist layer 87 may include a fourth opening OP4 located corresponding to the first opening OP1 in the first direction D1. The conductive material 44 may be formed after the patterned photoresist layer 87 is formed, and the conductive material 44 may be partly formed on the patterned photoresist layer 87 and partly formed in the dielectric layer 42. The patterned photoresist layer 87 and the conductive material 44 on the patterned photoresist layer 87 may then be removed for forming the gate structure GE.

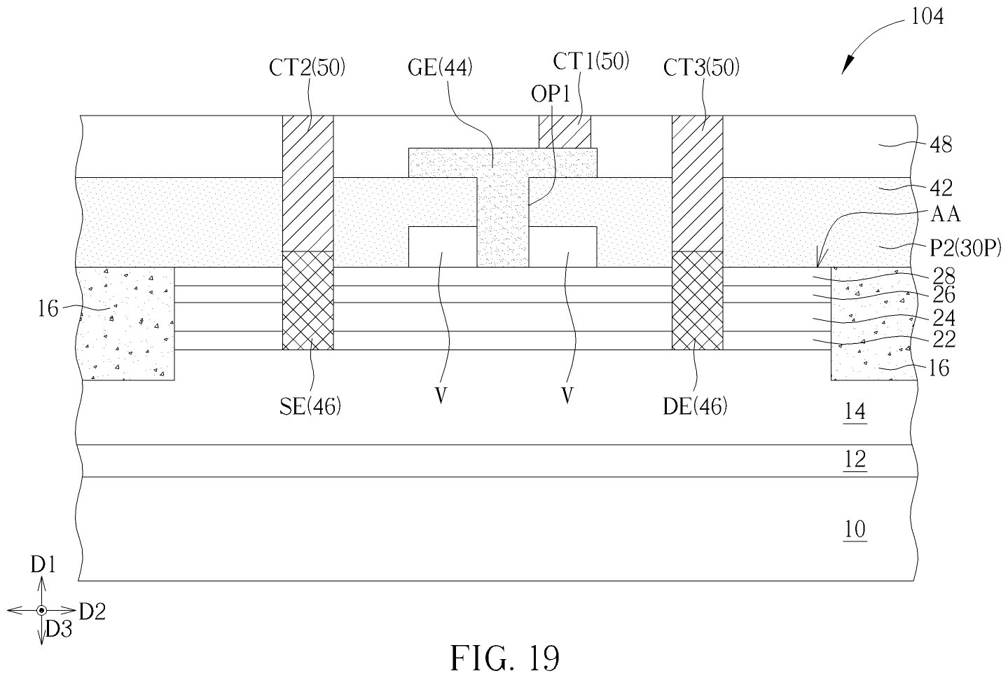

Please refer to FIG. 19. FIG. 19 is a schematic drawing illustrating a semiconductor device 104 according to a fourth embodiment of the present invention. As shown in FIG. 19, the semiconductor device 104 may include an isolation structure 16 surrounding the active region AA in the horizontal directions. In some embodiments, the isolation structure 16 may include a dielectric material and the isolation structure 16 may be regarded as a dielectric layer disposed on the sidewall of the active region AA, and a material composition of the isolation structure 16 may be different from the material composition of the dielectric layer 42. In some embodiments, the isolation structure 16 may be formed by performing an implantation process to a predetermined area of the material layers stacked on the substrate 10 (such as the III-V compound semiconductor layer 14, the barrier layer 22, the barrier layer 24, the barrier layer 26, and the cap layer 28 stacked on the substrate 10), and a top surface of the isolation structure 16 and a top surface of the active region AA may be substantially coplanar accordingly, but not limited thereto.

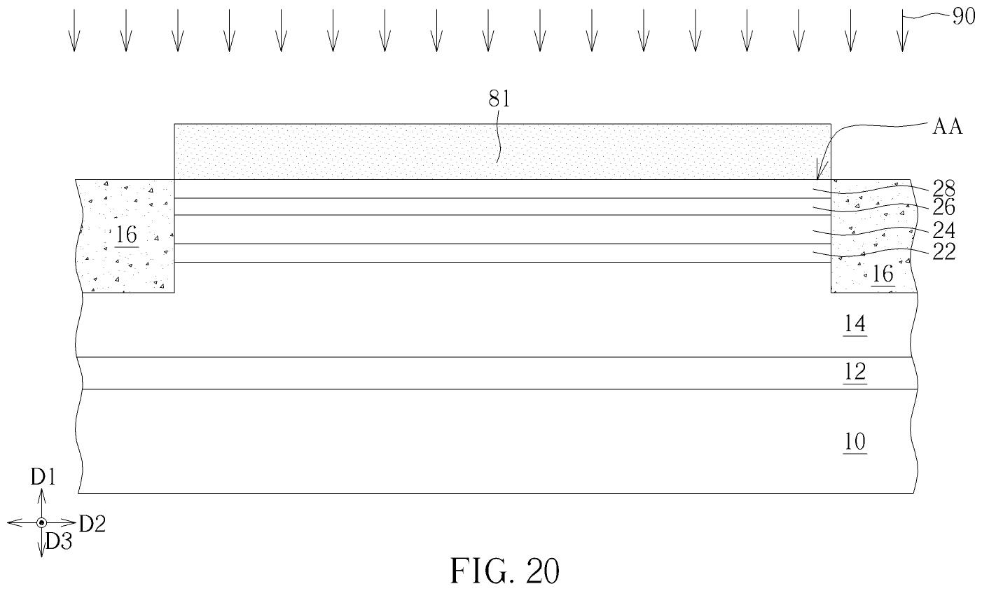

Please refer to FIG. 20 and FIG. 19. In some embodiments, FIG. 19 may be regarded as a schematic drawing in a step subsequent to FIG. 20, but not limited thereto. As shown in FIG. 20 and FIG. 19, after the step of forming the buffer layer 12, the III-V compound semiconductor layer 14, the barrier layer 22, the barrier layer 24, the barrier layer 26, and the cap layer 28 stacked on the substrate 10, a patterned photoresist layer 81 may be formed on the cap layer 28, and an implantation process 90 may be carried out by using the patterned photoresist layer 81 as a mask for forming the isolation structure 16 and the active region AA surrounding by the isolation structure 16. In other words, the isolation structure 16 may include the material layers stacked on the substrate 10 and impurities used in the implantation process 90, and a portion of the material layers stacked on the substrate 10 may be doped with the impurities used in the implantation process 90 for being converted into a dielectric layer. In some embodiments, the impurities used in the implantation process 90 may include positive ions, and a portion of the material layers stacked on the substrate 10 may be bombarded with the positive ions for being converted into a dielectric structure, but not limited thereto. After the step of forming the isolation structure 16, the patterned photoresist layer 81 may be removed, and the dielectric layer 42, the air void V, the gate structure GE, the first source/drain electrode SE, the second source/drain electrode DE, the dielectric layer 48, and the contact structures described above may be formed for forming the semiconductor device 104 shown in FIG. 19. It is worth noting that the isolation structure 16 and/or the manufacturing method thereof in this embodiment may also be applied to other embodiments of the present invention according to some design considerations. However, the active region AA may be the region surrounded by the isolation structure 16 or the mesa structure described above. In other words, the active region AA may be formed by the implantation process 90 or the active region AA may be the mesa structure formed by the patterning process described in the first embodiment, and the active region AA cannot be formed by both the implantation process 90 and the patterning process described in the first embodiment.

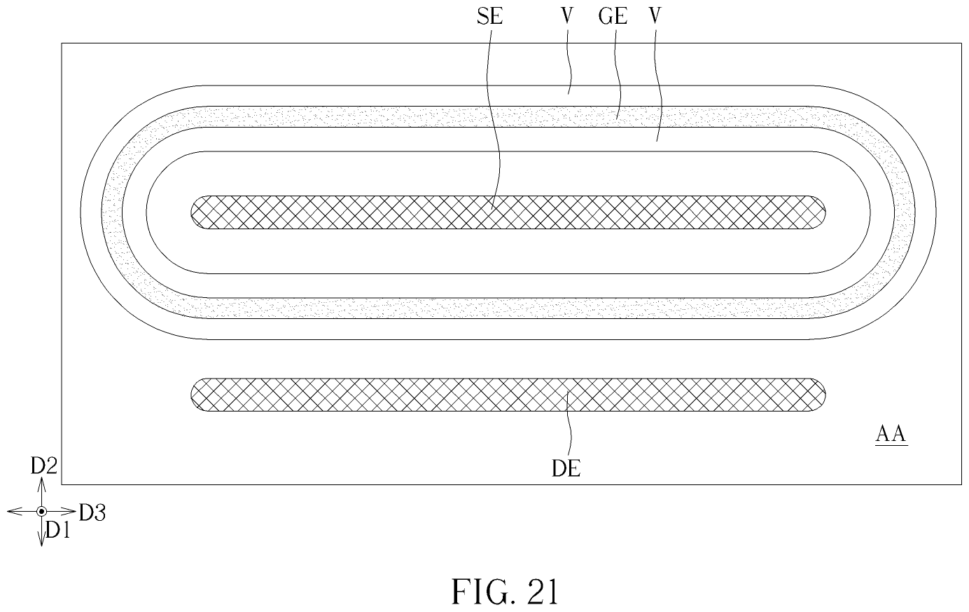

Please refer to FIG. 21. FIG. 21 is a schematic drawing illustrating a top view of a semiconductor device according to an embodiment of the present invention. It should be noted that some components in the semiconductor device (such as the dielectric layers and the contact structures described above) are not illustrated in FIG. 21 for the simplicity of the figure. As shown in FIG. 21, in some embodiments, an elongation direction of the first source/drain electrode SE and an elongation direction of the second source/drain electrode DE may be parallel with one another, and the gate structure GE and the air void V may surround the first source/drain electrode SE. For example, the first source/drain electrode SE and the second source/drain electrode DE may be elongated in the third direction D3, respectively, and the gate structure GE and the air void V may surround the first source/drain electrode SE in the horizontal directions (such as the second direction D2, the third direction D3, and other horizontal directions perpendicular to the first direction D1). It is worth noting that the allocations of the gate structure GE, the air void V, the first source/drain electrode SE, and the second source/drain electrode DE shown in FIG. 21 may be applied to other embodiments (such as the first embodiment, the second embodiment, the third embodiment, and/or the fourth embodiment described above) in the present invention according to some design considerations.

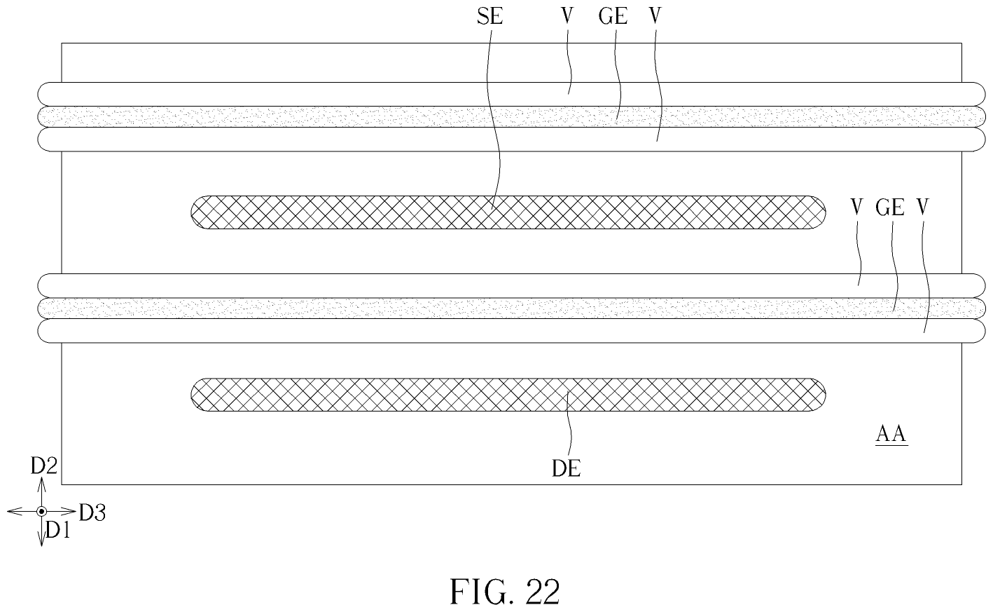

Please refer to FIG. 22. FIG. 22 is a schematic drawing illustrating a top view of a semiconductor device according to an embodiment of the present invention. It should be noted that some components in the semiconductor device (such as the dielectric layers and the contact structures described above) are not illustrated in FIG. 22 for the simplicity of the figure. As shown in FIG. 22, in some embodiments, an elongation direction of the air void V, an elongation direction of the gate structure GE, the elongation direction of the first source/drain electrode SE, and the elongation direction of the second source/drain electrode DE may be parallel with one another. For example, the air void V, the gate structure GE, the first source/drain electrode SE, and the second source/drain electrode DE may be elongated in the third direction D3, respectively. In addition, a plurality of gate structures GE and the corresponding air voids V may be disposed on the same active region AA, and each gate structure GE and the corresponding air void V may be partially disposed outside the active region AA, but not limited thereto. It is worth noting that the allocations of the gate structure GE, the air void V, the first source/drain electrode SE, and the second source/drain electrode DE shown in FIG. 22 may be applied to other embodiments (such as the first embodiment, the second embodiment, the third embodiment, and/or the fourth embodiment described above) in the present invention according to some design considerations.

To summarize the above descriptions, according to the semiconductor device and the manufacturing method thereof in the present invention, the air void disposed in the dielectric layer adjacent to the gate structure may be used to lower the equivalent dielectric constant of the material around the gate structure, and the density of trapped electrons and/or detrapped electrons from the gate structure and/or around the gate structure may be reduced accordingly. Some related issues of the semiconductor device (such as gate-lag, current collapse, and so forth) may be improved, and the operation performance and/or the reliability of the semiconductor device may be enhanced accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
at least one active region, wherein the at least one active region comprises a III-V compound semiconductor layer;
a first dielectric layer disposed on the at least one active region;
a gate structure disposed on the at least one active region, wherein at least a part of the gate structure is disposed in the first dielectric layer; and
an air void disposed in the first dielectric layer, wherein at least a part of the air void is disposed at two opposite sides of the gate structure in a horizontal direction.

2. The semiconductor device according to claim 1, wherein the air void is directly connected with the gate structure in the first dielectric layer.

3. The semiconductor device according to claim 1, wherein the air void surrounds a bottom portion of the gate structure in the first dielectric layer.

4. The semiconductor device according to claim 1, wherein the gate structure is partly disposed in the first dielectric layer and partly disposed on the first dielectric layer in a vertical direction.

5. The semiconductor device according to claim 4, wherein a part of the first dielectric layer is located between the gate structure and the air void in the vertical direction.

6. The semiconductor device according to claim 1, further comprising:
a first source/drain electrode; and
a second source/drain electrode, wherein the first source/drain electrode and the second source/drain electrode are disposed at two opposite sides of at least a part of the gate structure in the horizontal direction, respectively.

7. The semiconductor device according to claim 6, wherein a part of the air void is disposed between the gate structure and the first source/drain electrode in the horizontal direction, and another part of the air void is disposed between the gate structure and the second source/drain electrode in the horizontal direction.

8. The semiconductor device according to claim 6, wherein the gate structure and the air void surround the first source/drain electrode.

9. The semiconductor device according to claim 6, wherein an elongation direction of the air void, an elongation direction of the gate structure, an elongation direction of the first source/drain electrode, and an elongation direction of the second source/drain electrode are parallel with one another.

10. The semiconductor device according to claim 1, further comprising:
a second dielectric layer disposed on a sidewall of the at least one active region, wherein a material composition of the second dielectric layer is different from a material composition of the first dielectric layer.

11. A manufacturing method of a semiconductor device, comprising:
providing at least one active region, wherein the at least one active region comprises a III-V compound semiconductor layer;
forming a dielectric layer on the at least one active region;
forming an air void in the dielectric layer;
forming a gate structure on the at least one active region, wherein at least a part of the gate structure is formed in the dielectric layer, and at least a part of the air void is disposed at two opposite sides of the gate structure in a horizontal direction.

12. The manufacturing method of the semiconductor device according to claim 11, wherein the step of forming the air void comprises:
forming a patterned material layer on the at least one active region before the dielectric layer is formed, wherein the patterned material layer comprises a first portion covered by the dielectric layer; and
removing the first portion of the patterned material layer after the dielectric layer is formed and before the gate structure is formed for forming the air void in the dielectric layer.

13. The manufacturing method of the semiconductor device according to claim 12, wherein a material composition of the patterned material layer is different from a material composition of the dielectric layer.

14. The manufacturing method of the semiconductor device according to claim 12, wherein the step of forming the air void further comprises:
forming a first opening penetrating through the dielectric layer on the first portion of the patterned material layer for exposing the first portion of the patterned material layer before the step of removing the first portion of the patterned material layer.

15. The manufacturing method of the semiconductor device according to claim 14, wherein the step of forming the air void further comprises:
forming a first patterned photoresist layer on the dielectric layer after the first opening is formed and before the step of removing the first portion of the patterned material layer, wherein the first patterned photoresist layer comprises a second opening located corresponding to the first opening in a vertical direction, and a projection area of the second opening in the vertical direction is greater than a projection area of the first opening in the vertical direction.

16. The manufacturing method of the semiconductor device according to claim 15, wherein the step of forming the gate structure comprises:
forming a conductive material after the air void is formed, wherein the conductive material is partly formed on the first patterned photoresist layer, partly formed on the dielectric layer, and partly formed in the dielectric layer; and
removing the first patterned photoresist layer and the conductive material on the first patterned photoresist layer for forming the gate structure.

17. The manufacturing method of the semiconductor device according to claim 15, wherein the step of forming the gate structure comprises:
removing the first patterned photoresist layer after the air void is formed;
forming a second patterned photoresist layer on the dielectric layer after the first patterned photoresist layer is removed, wherein the second patterned photoresist layer comprises a third opening located corresponding to the first opening in the vertical direction;
forming a conductive material after the second patterned photoresist layer is formed, wherein the conductive material is partly formed on the second patterned photoresist layer and partly formed in the dielectric layer; and
removing the second patterned photoresist layer and the conductive material on the second patterned photoresist layer for forming the gate structure.

18. The manufacturing method of the semiconductor device according to claim 14, wherein the first opening OP1 is formed by an etching process using a third patterned photoresist layer formed on the dielectric layer as an etching mask, and the step of forming the gate structure comprises:
forming a conductive material after the air void is formed, wherein the conductive material is partly formed on the third patterned photoresist layer and partly formed in the dielectric layer; and
removing the third patterned photoresist layer and the conductive material on the third patterned photoresist layer for forming the gate structure.

19. The manufacturing method of the semiconductor device according to claim 12, wherein the patterned material layer further comprises a second portion located on a sidewall of the at least one active region, and the second portion is covered by the dielectric layer after the air void is formed.

20. The manufacturing method of the semiconductor device according to claim 11, further comprising:
forming a first source/drain electrode and a second source/drain electrode, wherein the first source/drain electrode and the second source/drain electrode are disposed at two opposite sides of at least a part of the gate structure in the horizontal direction, respectively, wherein a part of the air void is disposed between the gate structure and the first source/drain electrode in the horizontal direction, and another part of the air void is disposed between the gate structure and the second source/drain electrode in the horizontal direction.
